(19) United States
(12) Patent Application Publication
(10) Pub. No.: US 2013/0206708 A1
(43) Pub. Date: Aug. 15, 2013

(54) SOLAR PANEL DEPLOYMENT SYSTEM

(71) Applicant: George Gregory Lessard, Ottawa (CA)

(72) Inventor: George Gregory Lessard, Ottawa (CA)

(21) Appl. No.: 13/808,325

(22) PCT Filed: Jun. 30, 2011
(86) PCT No.: PCT/CA11/50406

§ 371 Date: Mar. 18, 2013

(30) Foreign Application Priority Data
Jul. 5, 2010 (CA) 2712036

(51) Int. Cl. H01L 31/042

(52) U.S. Cl. CPC H01L 31/0422
USPC 211/1.52; 211/26; 211/163

(57) ABSTRACT

Systems and devices for deploying solar modules. A ladder frame having multiple solar modules is hinged with a base. The ladder frame is coupled to the base and is rotatable about an edge axis. Each one of the multiple solar modules is connected to the ladder frame by a panel frame, with the panel frame joining the solar modules to the ladder frame. Each panel frame can be independently rotatable about its own panel axis. The ladder frame is actuated by at least one base motor, with the inclination of the ladder frame being determined by the at least one base motor. Each panel frame (and the solar module attached to it) can be rotated by at least one panel motor. The system may be controlled by a control computer that, throughout the day, adjusts the deployment of the ladder frame and the angle of the solar modules to maximise the exposure of the solar modules to direct sunlight. The system may also be used for advertising by deploying advertising panels in place of or in addition to the solar modules.

### TECHNICAL FIELD

The present invention relates to solar modules. More specifically, the present invention relates to a system for deploying these solar modules and for adjusting their deployment such that the exposure of the solar modules to the sun is maximized by maintaining the solar modules as close to perpendicular as possible to the sun to ensure high output.

### BACKGROUND OF THE INVENTION

The increasing price of energy, whether it be from fossil fuels, nuclear energy, or other alternative forms of energy, has been a constant fact of life in the late 20^{th} and early 21^{st} centuries. This has led to a renewed interest in cheaper, more abundant sources of energy.

While solar energy has been harnessed for generations, recent technology has made it possible to make solar arrays feasible and viable for a greater clientele. Currently in the northern hemisphere, the optimal direction to arrange a stationary solar array is with a southward facing direction and vice-versa for the southern hemisphere. The closer to the equator that a solar array is located, the less there is of a need for dual axis tracking as the sun moves more overhead. As an example, while sunlight may be plentiful in some areas (such as the American southwest), the nature of the sun is that solar panels which harvest solar energy are not always at or near their peak efficiency. This is caused by the restriction in mounting options which current solar arrays offer.

It should be noted that solar modules that track the sun are known in the art and are actually in use in large solar energy farms and medium sized rural establishments. However, these current devices are inaccurate and far from optimal because of their simple software, their expensive installation fees, and they are not conducive to being deployed by residential homeowners, commercial and industrial buildings and rural establishments. Previously, solar trackers and solar positioners were required to be either ground mounted or mounted on the flat roof of a steel frame commercial/industrial building.

To address the growing energy needs of the early 21^{st} century, the market penetration of solar energy will need to be increased as this will reduce dependency on fossil fuel based energy. This may be fostered by having a lightweight, easy to assemble, effective, and accessible solar module assembly that maximises the solar exposure of the module regardless of the time of day.

There is therefore a need to mitigate if not overcome the shortcomings of the prior art.

### SUMMARY OF INVENTION

The present invention provides systems and devices for deploying solar modules. A ladder frame having multiple solar modules is hinged with a base. The ladder frame is coupled to the base and is rotatable about an edge axis. Each one of the multiple solar modules is connected to the ladder frame by a panel frame, with the panel frame joining the solar modules to the ladder frame. Each panel frame can be independently rotatable about its own panel axis. The ladder frame is actuated by at least one base motor, with the inclination of the ladder frame being determined by the at least one base motor. Each panel frame (and the solar module attached to it) can be rotated by at least one panel motor. In one implementation, a plurality of solar modules and panel frames can be run from a single base motor. The ladder frame may be angled with the base using the base motor while each panel frame/solar module may be angled about its panel axis using its panel motor. One implementation uses a plurality of panel frames and solar modules conjoined by means of gearing. In this implementation, any means of applying a force which can directly or indirectly transferred to the rotational frames on the invention may be used. Alternatively, the solar modules, if each is running on at least one base motor, may all be synchronised so that all the solar panels are uniformly angled about their respective panel axes. The system may be controlled by a control computer that, throughout the day, adjusts the deployment of the ladder frame and the angle of the solar modules to maximize the exposure of the solar modules to sunlight.

In a first aspect, the present invention provides a system for mounting at least one solar module, the system comprising:
a base
a ladder frame comprising at least one solar module, said ladder frame being hinged with said base at a base edge of said ladder frame, said ladder frame being rotatable about an edge axis adjacent and parallel to said base edge

wherein
each of said at least one module comprises a solar module coupled to a panel frame, said solar panel and panel frame being rotatable about a panel axis, said panel axis being parallel to an edge of said solar panel.

In a second aspect, the present invention provides a mounting system for mounting a plurality of movable panels, the system comprising:
a base;
a ladder frame comprising a plurality of panels, said ladder frame being hinged with said base at a base edge of said ladder frame, said ladder frame being rotatable about an edge axis adjacent and parallel to said base edge;

wherein
each of said plurality of panels comprises a panel coupled to said ladder frame by a panel frame, said panel and panel frame being rotatable about a panel axis, said panel axis being parallel to an edge of said panel.

Each of the panels may be equipped with poster style advertising and/or digital advertising. The digital advertising may be light emitting diodes (LEDs), liquid crystal displays (LCDs), plasma displays, or any other means for projecting images, video and/or audio.

### BRIEF DESCRIPTION OF THE DRAWINGS

The embodiments of the present invention will now be described by reference to the following figures, in which identical reference numerals in different figures indicate identical elements and in which:

FIGS. 1 and 2 are diagrams illustrating a mounting system according to one aspect of the invention;

FIG. 3A is a back view of a non-deployed panel frame according to one aspect of the invention;

FIG. 3B is a back view of a deployed panel frame from FIG. 3A;

FIG. 4 is a block diagram of a control scheme for the system according to another aspect of the invention.

### DETAILED DESCRIPTION OF THE INVENTION

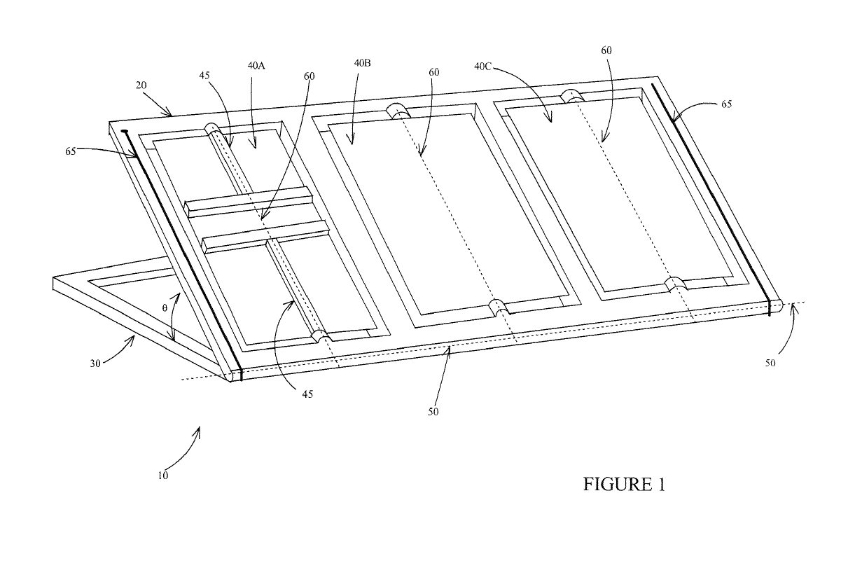

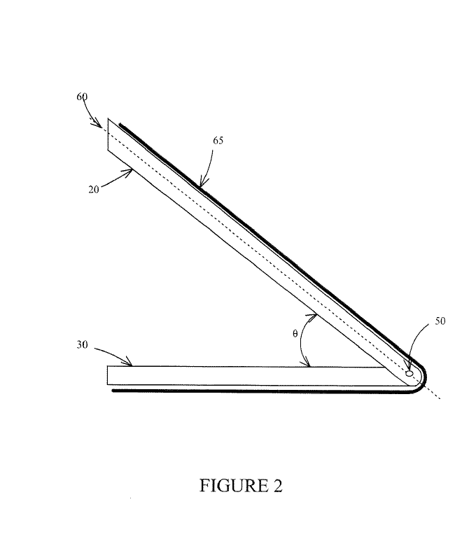

Referring to FIGS. 1 and 2, diagrams of the system 10 according to one aspect of the invention are presented. A ladder frame 20 is illustrated as being hinged to a base 30. The ladder frame 20 has a number of solar modules 40A, 40B, 40C, each solar module being mounted to the ladder frame by a panel frame 45. The ladder frame 20 is rotatable about an edge axis 50 while each solar module 40 is rotatable about a panel axis 60. As can be seen from the Figures, each panel axis 60 may be perpendicular to the edge axis 50. It should be noted that in FIG. 1, solar module 40A has its working or front side facing the base while solar modules 40B and 40C have their front or working sides facing away from the base. The panel frame 45 for solar module 40A is shown for illustration.

The ladder frame's deployment (i.e. its angle with the base) may be adjusted using a direct drive motor or by using a cable and motor system. For the cable and motor system, a cable is attached to the top of the ladder frame and is also tensioned with a motor. Activating the motor pulls on the cable and thereby causes an angle θ between the base and the ladder frame to increase. Increasing the angle between the ladder frame and the base thereby “raises” the frame while decreasing the angle “lowers” the ladder frame. The cable 65 can be seen in FIGS. 1 and 2.

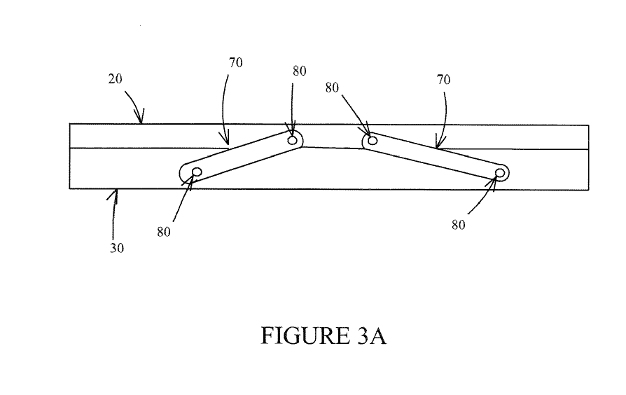

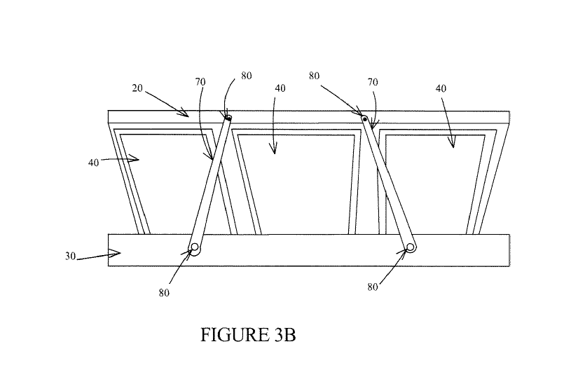

The ladder frame's deployment may also be adjusted using hydraulic, pneumatic or electric linear actuators as illustrated in FIGS. 3A and 3B. FIG. 3A shows a back view of a non-deployed ladder frame with the base. Hydraulic actuators 70 can be seen in the Figure. Each hydraulic actuator is coupled to the base and the ladder frame at hinge points 80. Actuating the hydraulic actuators raises the ladder frame. As the hydraulic actuators lengthen, the ladder frame pivots about the edge axis and is raised, thereby increasing the angle defined by the ladder frame and the base. Referring to FIG. 3B, a back view of the deployed ladder frame is illustrated, clearly showing the hydraulic actuators 70. When not deployed, it is preferable that the ladder frame, with the solar modules aligned and flat as well, be able to lay substantially flat on the base. The solar modules mounted with the panel frames are not only able to lay flat but are able to be inverted, allowing the working area of the solar module to face the base to minimise unwanted debris and to aid in maximising output. This feature also helps in keeping the solar modules clear of snow in the winter.

Systems other than the hydraulic actuators or the motor and cable systems noted above may be used to raise or lower the frame. Preferably, such systems provide a smooth, controllable travel from a lowered frame to a raised frame. As well, it is preferable that the deployment (i.e. the angle between the base and the frame) be controllable so that the solar modules' exposure to the sun may be increased if not maximized.

Regarding the base, the base is preferably of heavy enough construction or it may be weighted down so that the system does not tilt over when the frame is deployed. Alternatively, the base may be of the same construction of the ladder frame and may be securely bolted down to the floor or roof where the system is located. When the system is installed on a residential sloped roof, the base should be securely attached to the trusses in the roof to maintain building integrity.

Regarding the solar modules 40, each solar module is mounted on a panel frame 45 which rotates about its panel axis. The panel axis may be longitudinally in the middle of the module or, alternatively, the panel axis may be latitudinally in the middle of the module. Other configurations for the panel axis may be used but it has been found that placing the panel axis approximately in the middle of the module provided the best results. Offsetting the panel axis from the middle may also be tried but this may not yield the best results.

Preferably, each panel frame is rotatable by 360 degrees (both clockwise and anticlockwise) about its panel axis. Such a configuration would allow for the greatest freedom in terms of tilting the module. The module can thus be tilted properly so that solar exposure is maximized regardless of where the sun is. As well, if desired, the solar module may be rotated so that the solar module side (or the working side) is facing the base as is the case with module 40A in FIG. 1. Once the solar panel side is facing the base, the frame's deployment may be set so that the solar module side is protected from damage by the elements. This may be useful in the event meteorological occurrences which can damage the panel, such as snow, hail, sand or dust storms, are about to occur.

To rotate or tilt each panel/module assembly, a direct drive motor may be used with a single motor for each module. By properly controlling the rotation of the motor, the angle at which the module tilts can be carefully controlled. This control of the module's tilt angle allows for an increase or a maximization of the module's exposure to the sun. Using a single motor for each module allows for tilting each module independently of the other modules.

Alternatively, the solar modules may be tilted as a group. Use of a worm drive and a low rpm (revolution per minute) single drive motor, with suitable gearing at each panel axis, can simultaneously turn all the modules to the same tilt angle. Again, it would be preferable if the solar modules and panel frames can be rotated by about 360 degrees both clockwise and anticlockwise to allow for the varying positions of the sun. Such an arrangement can maximize the solar exposure of each group of modules.

Other means for tilting/rotating the solar panels may, of course, be used. Different types of gearing mechanisms, using helical, worm, spur, bevel, etc. gears may be used. Depending on the implementation, chains, cables, and other means for translating one type of motion into rotational motion for the panels may be used.

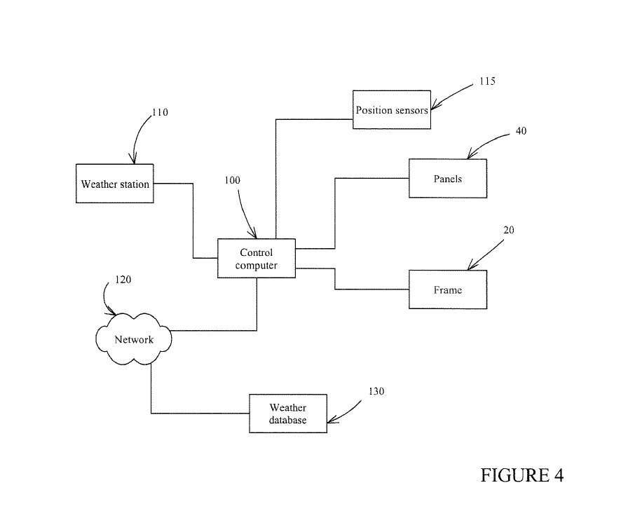

Referring to FIG. 4, a block diagram of a control scheme for the system is illustrated. A control computer 100 controls the rotation of ladder frame and the panel frame(s). The computer determines the deployment of the ladder frame and the rotation or tilt of the various panel frames to maximize the solar exposure of the modules. The various deployment settings for the ladder frame and the panel frame(s) can be pre-programmed into the control computer and may be time dependent and season/date dependent. As such, the control computer 100 can adjust the deployment angle for the frame and the tilt of the modules depending on the time of day and on the date. Alternatively, the control computer can be programmed to search for the optimum mix of settings for the ladder frame and the panel frame every few seconds to maximize the solar exposure of the solar modules given the current weather conditions and position of the sun.

As can be seen from FIG. 4, the control computer 100 separately controls the panel frame(s) and the ladder frame. In one variant, the control computer 100 can be two computers, each separately controlling the frame or the panels. Also as can be seen in FIG. 4, a weather station 110 can be coupled to the control computer 100. The weather station 110 can determine the prevailing conditions and, based on these conditions, the control computer 100 can deploy the panels accordingly. As an example, if the prevailing weather conditions are not conducive to the deployment of a solar array (e.g. rain, hail, night time, clouds), the control computer can ensure that the ladder frame, panel frames and solar modules are properly configured to minimize the possibility of damage to the panels and to not waste valuable electricity. Preferably, the control computer can operate using either DC or AC current. Also, if the weather conditions, as sensed by the weather station (e.g. wind speed), are not conducive to the use of the solar panels in that the panels may get damaged, the control computer can lower the ladder frame and retract the modules so that their working surface is configured to face the base to prevent damage to the modules.

It should be noted that the weather station may be equipped with various instruments and devices which may be useful in determining the prevailing weather condition and which may be useful in communication with the control computer. To this end, hygrometers, barometers, thermometers, anemometers, and other weather measuring and detecting devices may be placed on the weather station. As well, a wireless connection between the weather station and the control computer may be used to transfer data between the two devices.

With the weather station coupled or in communication with the computer, this allows for real-time monitoring of weather data as well as the crossed-referencing of this data by software. This enables the automatic interaction of the ladder frame and the panel frame(s) depending on wind speeds, snow loads, levels of sunlight and other factors that are not optimal for the harnessing of solar energy.

The weather station 110 in FIG. 4 may take the form of a sun tracking control subsystem that tracks the passage of the sun through the sky and accordingly adjusts the tilt of the various panels and the deployment of the ladder frame to increase or maximize the solar exposure of the modules. As an alternative to the existing sun tracking systems currently available, instead of tracking the hottest spot in the sky (presumably the sun), the sun tracking control subsystem may track the brightest spot in the sky. As such, even with cloudy skies, the sun positioning subsystem will track the sun.

The control computer 100 may control the various motors used in the system by means of suitable A/C or D/C control devices. The control computer 100 can, using a feedback loop, sense the speed of each motor and, depending on the speed, adjust the speed or torque accordingly to arrive at the correct tilt angle or deployment angle for the ladder frame or the relevant module.

Again referring to FIG. 4, the control computer 100 may also be coupled to or in communication with position sensors 115. These position sensors 115 may sense the tilt angle of the various modules or the deployment angle of the ladder frame. The position sensors can provide a feedback path for the control computer so that the deployment angle between the ladder frame and the base or the tilt angle of the various modules can be more accurately controlled.

Also shown in FIG. 4 is a connection between the control computer and a network 120. The network 120 may include any known types of networks (wired, wireless, etc.) and may encompass a connection to the Internet. The network 120 serves as a communications conduit between the control computer and a weather mapping database 130. The readings from the weather station 110 may be entered into the weather database 130 by way of the control computer. Alternatively, the control computer may retrieve weather readings from the database 130 and, based on these readings, the control computer may retract the ladder frame and the modules. As an example, if weather readings from the database indicate an impending wind storm, the control computer may retract ladder frame and modules to prevent damage.

It should be noted that control computers for controlling various devices and motors are currently available and may be adapted to control the ladder frame and the panel frames of the system by a person skilled in the art.

Regarding the construction of the frames, the frames may be constructed from any suitable material that can withstand the shearing forces applied to the frames when being deployed. As well, the material used should also be able to withstand prolonged exposure to the elements. Finally, it would be preferred if the material was relatively light so as not to need an overly powerful motor to be used for raising or lowering the frame. It has been found that aluminum may be used as well as stainless steel and any suitable composite materials in the construction of the frame.

Regarding the panel frames, these panel frames may be framed using the same material as that for the construction of the ladder frame. The panel frames and solar modules are then coupled to the ladder frame so that the panel frames and their associated solar modules are rotatable about each panel's panel axis as noted above. As can be seen in FIG. 1, the panel frame may have a T-shaped construction to provide support for the solar module. Other configurations for the panel frame may be used in place of the T-shaped configuration in FIG. 1.

Again regarding the panels, any suitable solar panel may be used including solar photovoltaic (electric), thermal liquid, thermal air, and water heating. Depending on the size of the solar modules, the framing for the solar modules may be adjusted accordingly and, as well, the sizing of the frame may be adjusted to accommodate the modules.

It should, however, be noted that, while the above description relates to the use of the system with solar panels, other panels may be used as well. As an example, advertising panels may be used in place or along with solar panels. Since each panel has two sides, each side may be used for advertising while the other side may be used for another advertiser or for solar energy generation. Depending on the programming of the control computer, when the sun is out the solar modules can be harnessing electricity and when the sun is not out the solar module can be inverted to reveal advertising. In another embodiment, one advertiser may be given exposure for a certain portion of the day while the other advertiser may be given exposure for the rest of the day. The frame can thus be deployed to provide public exposure to one or the other side of the panels. At a certain time of the day, each panel can be automatically rotated to provide exposure to the other side of the panel.

For implementations which use advertising panels, the advertising panels may be equipped with poster style advertising and/or digital advertising. The digital advertising may be light emitting diodes (LEDs), liquid crystal displays (LCDs), plasma displays, or any other means for projecting images, video and/or audio.

While the above description describe a single frame with multiple solar modules, multiple frames can be placed together to obtain better power generation capabilities and can all be controlled using a single control computer. It should also be noted that the frame may have as few as a single solar panel and perhaps as many as 15 or more solar panels. Of course, the actual configuration may be dependent on the size of the solar module used as well as the motors or actuators used to tilt and deploy the frame and panels.

A person understanding this invention may now conceive of alternative structures and embodiments or variations of the above all of which are intended to fall within the scope of the invention as defined in the claims that follow.

Having thus described the invention, what is claimed as new and secured by Letters Patent is:

1. A system for mounting at least one solar module, the system comprising:
a base
a ladder frame comprising at least one solar module, said ladder frame being hinged with said base at a base edge of said ladder frame, said ladder frame being rotatable about an edge axis adjacent and parallel to said base edge.
wherein
each of said at least one module comprises a solar module coupled to a panel frame, said solar panel and panel frame being rotatable about a panel axis, said panel axis being parallel to an edge of said solar panel.

2. A system according to claim 1 wherein said system further comprises base motor means for adjustably rotating said ladder frame about said edge axis such that said ladder frame forms an angle with said base.

3. A system according to claim 1 wherein said system further comprises at least one panel frame motor means for each of said plurality of modules, each panel motor means being for adjustably rotating a module about its panel axis.

4. A system according to claim 1 wherein said system further comprises motor control means for controlling motors which adjustably rotate said ladder frame about said edge axis.

5. A system according to claim 4 wherein said motor control means further controls motors which adjustably rotate said solar modules about their panel frame axes.

6. A system according to claim 4 wherein said motor control means are controlled by a sun positioning control subsystem, said sun control subsystem being for tracking said sun and for adjusting a deployment of said ladder frame to maximize an exposure to the sun of said solar modules.

7. A system according to claim 5 wherein said motor control means are controlled by a sun positioning control subsystem, said sun control subsystem being for tracking said sun and for adjusting a deployment of said solar modules to maximize an exposure to the sun of said solar modules.

8. A system according to claim 1 wherein each solar module is rotatably independent of other solar modules in said ladder frame.

9. A system according to claim 1 wherein each panel axis is perpendicular to said edge axis.

10. A system according to claim 1 wherein a tilt angle of said module and a deployment of said ladder frame are controlled by a control computer.

11. A system according to claim 10 further including a weather station for determining prevailing weather conditions, wherein said weather station sends readings to said control computer, said control computer using said readings to determine a suitable tilt angle for said modules and deployment for said frame.

12. A mounting system for mounting a plurality of movable panels, the system comprising:
a base;
a ladder frame comprising a plurality of panels, said ladder frame being hinged with said base at a base edge of said ladder frame, said ladder frame being rotatable about an edge axis adjacent and parallel to said base edge;
wherein
each of said plurality of panels comprises a panel coupled to said ladder frame by a panel frame, said panel and panel frame being rotatable about a panel axis, said panel axis being parallel to an edge of said panel.

13. A system according to claim 12 wherein at least one side of said panel is used for advertising.

14. A system according to claim 12 wherein at least one of said panels is a solar panel for converting solar energy into electricity.
